(19) United States
(12) Patent Application Publication
(10) Pub. No.: US 2011/0056539 A1
(43) Pub. Date: Mar. 10, 2011

(54) ASSEMBLIES COMPRISING A THERMALLY AND DIMENSIONALLY STABLE POLYIMIDE FILM, AN ELECTRODE AND AN ABSORBER LAYER, AND METHODS RELATING THERETO

(75) Inventors: Brian C Auman, Pickerington, OH (US); Salah Boussaad, Wilmington, DE (US); Thomas Edward Carney, Orient, OH (US); Kostantinos Kourtakis, Media, PA (US); John W. Simmons, Wilmingston, DE (US)

(73) Assignee: E.I. DU PONT DE NEMOURS AND COMPANY, Wilmington, DE (US)

(21) Appl. No.: 12/991,203

(22) PCT Filed: May 18, 2009
(86) PCT No.: PCT/US09/44285

§ 371 Date: Nov. 5, 2010

(51) Int. Cl. H01L 31/042; H01L 31/0224; H01L 31/032

(52) U.S. Cl. 136/249; 136/252; 136/262; 136/265

(57) ABSTRACT

The assemblies of the present invention comprise an electrode, an absorber layer and a polyimide film. The polyimide film contains from about 40 to about 95 weight percent of a polyimide derived from: i. at least one aromatic dianhydride, at least about 85 mole percent of such aromatic dianhydride being a rigid rod type dianhydride, and ii. at least one aromatic diamine, at least about 85 mole percent of such aromatic diamine being a rigid rod type diamine. The polyimide films of the present disclosure further comprise a filler that: i. is less than about 800 nanometers in at least one dimension; ii. has an aspect ratio greater than about 3:1 ; iii. is less than the thickness of the polyimide film in all dimensions; and iv. is present in an amount from about 5 to about 60 weight percent of the total weight of the polyimide film.

### FIELD OF DISCLOSURE

This disclosure relates generally to assemblies comprising an absorber layer, an electrode, and a polyimide film, where the polyimide film has: i. advantageous dielectric properties; and ii. advantageous thermal and dimensional stability over a broad temperature range, even in the presence of tension or other dimensional stress. More specifically, the assemblies of the present disclosure are well suited for the manufacture of monolithically integrated solar cells, particularly monolithically integrated solar cells comprising a copper/indium/gallium/di-selenide (CIGS) or similar-type absorber layer.

### BACKGROUND OF THE DISCLOSURE

To address an increasing need for alternative energy sources, there is currently a strong interest in developing light-weight, efficient photovoltaic systems (e.g., photovoltaic cells and modules). Of particular interest are photovoltaic systems having a copper/indium/gallium/di-selenide (CIGS) absorber layer. With such systems, a high temperature annealing step is generally applied to improve absorber layer performance. The annealing step is typically conducted during manufacture and is typically applied to an assembly, comprising a substrate, a bottom electrode and the CIGS absorber layer. The substrate must have thermal and dimensional stability at the annealing temperature(s), and therefore conventional substrates have typically comprised metal or ceramic (conventional polymeric materials tend to lack sufficient thermal and dimensional stability, particularly at peak annealing temperatures). However, ceramics, such as glass, lack flexibility and can be heavy, bulky and subject to breakage. Metals can be less prone to such disadvantages, but metals tend to conduct electricity, which tends to also be a disadvantage, e.g., inhibits monolithic integration of CIGS photovoltaic cells. Hence, there exists a need for CIGS type assemblies comprising a polymeric substrate having sufficient thermal and dimensional stability (and also sufficient dielectric properties), that the assembly: (a) can be manufactured by a relatively economical process, such as, reel-to-reel or similar-type processing, (b) enables relatively simple, straightforward monolithic integration of thin film photovoltaic cells, e.g., by reel-to-reel or similar type manufacturing processes, and (c) can adequately tolerate desired annealing temperatures during fabrication of the assembly.

### SUMMARY OF THE INVENTION

The assemblies of the present disclosure comprise a polyimide film having a thickness from about 8 to about 150 microns. The polyimide film contains from about 40 to about 95 weight percent of an aromatic polyimide derived from: i. at least one aromatic dianhydride, at least about 85 mole percent of such aromatic dianhydride being a rigid rod dianhydride, ii. at least one aromatic diamine, at least about 85 mole percent of such aromatic diamine being a rigid rod diamine. The polyimide films of the present disclosure further comprise a filler that: i. is less than about 800 nanometers in at least one dimension; ii. has an aspect ratio greater than about 3:1; iii. is less than the thickness of the polyimide film in all dimensions; and iv. is present in an amount from about 5 to about 60 weight percent of the total weight of the polyimide film. The assemblies of the present disclosure further comprise an absorber layer and an electrode, where the electrode is between the absorber layer and the polyimide film, and the electrode is in electrical communication with the absorber layer.

### BRIEF DESCRIPTION OF THE DRAWING

The accompanying drawing, which is incorporated in and form a part of the specification, illustrate the preferred embodiment of the present invention, and together with the descriptions serve to explain the principles of the invention.

In the Drawing:

The FIGURE is a sectional view of a thin-film solar cell fabricated on a polyimide film, constructed in accordance with the present invention.

### DETAILED DESCRIPTION

### Definitions

“Film” is intended to mean a free-standing film or a coating on a substrate. The term “film” is used interchangeably with the term “layer” and refers to covering a desired area.

“Monolithic integration” is intended to mean integrating (either in series or in parallel) a plurality of photovoltaic cells to form a photovoltaic module, where the cells/module can be formed in a continuous fashion on a single film or substrate, e.g., a reel to reel operation.

“GIGS/CIS” is intended to mean an absorber layer, either on its own or as part of a combination of layers, such as, in combination with an electrode, or in combination with an electrode and a polyimide film, or as part of a photovoltaic cell or module, (depending upon context) where the absorber layer (or at least one absorber layer) comprises: i. a copper indium gallium di-selenide composition; ii. a copper indium gallium disulfide composition; iii. a copper indium di-selenide composition; iv. a copper indium disulfide composition; or v. any element or combination of elements that could be substituted for copper, indium, gallium, di-selenide, and/or disulfide, whether presently known or developed in the future.

“Dianhydride” as used herein is intended to include precursors or derivatives thereof, which may not technically be a dianhydride but would nevertheless react with a diamine to form a polyamic acid which could in turn be converted into a polyimide.

Similarly, “diamine” as used herein is intended to include precursors or derivatives thereof, which may not technically be a diamine but would nevertheless react with a dianhydride to form a polyamic acid which could in turn be converted into a polyimide.

As used herein, the terms “comprises,” “comprising,” “includes,” “including,” “has,” “having” or any other variation thereof, are intended to cover a non-exclusive inclusion. For example, a method, process, article, or apparatus that comprises a list of elements is not necessarily limited to only those elements but may include other elements not expressly listed or inherent to such method, process, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, articles “a” or “an” are employed to describe elements and components of the invention. This is done merely for convenience and to give a general sense of the invention. This description should be read to include one or at least one and the singular also includes the plural unless it is obvious that it is meant otherwise.

The polyimide films used in the assemblies of the present disclosure resist shrinkage or creep (even under tension, such as, reel to reel processing) within a broad temperature range, such as, from about room temperature to temperatures in excess of 400° C., 425° C. or 450° C.

In one embodiment, the polyimide film changes in dimension by less than 1, 0.75, 0.5, or 0.25 percent when subjected to a temperature of 450° C. for 30 minutes while under a stress in a range from 7.4-8.0 MPa (mega Pascals). In some embodiments, the polyimide films of the present disclosure have sufficient dimensional and thermal stability to be a viable alternative to metal or ceramic support materials.

The assemblies of the present disclosure can be used, for example, in thin film solar cells. When used in a CIGS/CIS application, the polyimide films of the present disclosure can provide a thermally and dimensionally stable, flexible film upon which a bottom electrode (such as, a molybdenum electrode) can be directly formed on the polyimide film surface. Over the bottom electrode, an absorber layer can be applied in a manufacturing step toward the formation of a CIGS/CIS photovoltaic cell. In some embodiments, the bottom electrode is flexible. The polyimide film can be reinforced with thermally stable, inorganic: fabric, paper (e.g., mica paper), sheet, scrim or combinations thereof. In some embodiments, the polyimide film of the present disclosure has adequate electrical insulation properties to allow multiple CIGS/CIS photovoltaic cells to be monolithically integrated into a photovoltaic module. In some embodiments, the polyimide films of the present disclosure provide:

i. low surface roughness, i.e., an average surface roughness (Ra) of less than 1000, 750, 500, 400, 350, 300 or 275 nanometers;

ii. low levels of surface defects; and/or

iii. other useful surface morphology, to diminish or inhibit unwanted defects, such as, electrical shorts.

In one embodiment, the polyimide films used in the assemblies of the present disclosure have an in-plane CTE in a range between (and optionally including) any two of the following: 1, 5, 10, 15, 20, and 25 ppm/° C., where the in-plane coefficient of thermal expansion (CTE) is measured between 50° C. and 350° C. In some embodiments, the CTE within this range is further optimized to further diminish or eliminate unwanted cracking due to thermal expansion mismatch of any particular supported material selected in accordance with the present disclosure (e.g., the CIGS/CIS absorber layer in CIGS/CIS applications). Generally, when forming the polyimide, a chemical conversion process (as opposed to a thermal conversion process) will provide a lower CTE polyimide film. This is particularly useful in some embodiments, as very low CTE (<10 ppm/° C.) values can be obtained, closely matching those of the delicate conductor and semiconductor layer deposited thereon. Chemical conversion processes for converting polyamic acid into polyimide are well known and need not be further described here. The thickness of a polyimide film can also impact CTE, where thinner polyimide films tend to give a lower CTE (and thicker polyimide films, a higher CTE), and therefore, polyimide film thickness can be used to fine tune polyimide film CTE, depending upon any particular application selected. The polyimide films used in the assemblies of the present disclosure have a thickness in a range between (and optionally including) any of the following thicknesses (in microns): 8, 10, 12, 15, 20, 25, 50, 75, 100, 125 and 150 microns. Monomers and fillers within the scope of the present disclosure can also be selected or optimized to fine tune CTE within the above range. Ordinary skill and experimentation may be necessary in fine tuning any particular CTE of the polyimide films of the present disclosure, depending upon the particular application selected for the assemblies. The in-plane CTE of the polyimide film can be obtained by thermomechanical analysis utilizing a TA Instruments TMA-2940 run at 10° C./min, up to 380° C., then cooled and reheated to 380° C., with the CTE in ppm/° C. obtained during the reheat scan between 50° C. and 350° C.

The polyimide films used in the assemblies of the present disclosure should have high thermal stability so the polyimide films do not substantially degrade, lose weight, have diminished mechanical properties, or give off significant volatiles, e.g., during the absorber layer deposition and/or annealing process in a CIGS/CIS application of the present disclosure. In a CIGS/CIS application, in one embodiment the polyimide film should be thin enough to not add excessive weight to the photovoltaic module, but thick enough to provide high electrical insulation at operating voltages, which in some cases may reach 400, 500, 750 or 1000 volts or more.

In accordance with the present disclosure, a filler is added to the polyimide film to increase the polyimide storage modulus. In some embodiments, the filler will maintain or lower the coefficient of thermal expansion (CTE) of the polyimide layer while still increasing the modulus. In some embodiments, the filler increases the storage modulus above the glass transition temperature (Tg) of the polyimide film. The addition of filler typically allows for the retention of mechanical properties at high temperatures and can improve handling characteristics. The fillers of the present disclosure:

1. have a dimension of less than 800 nanometers (and in some embodiments, less than 750, 650, 600, 550, 500, 475, 450, 425, 400, 375, 350, 325, 300, 275, 250, 225, or 200 nanometers) in at least one dimension (since fillers can have a variety of shapes in any dimension and since filler shape can vary along any dimension, the “at least one dimension” is intended to be a numerical average along that dimension);

2. have an aspect ratio greater than 3, 4, 5, 6, 7, 8, 9, 10, 11, 12, 13, 14, or 15 to 1 ;

3. is less than 100, 95, 90, 85, 80, 75, 70, 65, 60, 55, 50, 45, 40, 35, 30, 25, 20, 15 or 10 percent of the thickness of the polyimide film in all dimensions; and

4. is present in an amount between and optionally including any two of the following percentages: 5, 10, 15, 20, 25, 30, 35, 40, 45, 50, 55, and 60 weight percent, based upon the total weight of the polyimide film.

Suitable fillers are generally stable at temperatures above 450° C., and in some embodiments do not significantly decrease the electrical insulation properties of the polyimide film. In some embodiments, the filler is selected from a group consisting of needle-like fillers, fibrous fillers, platelet fillers and mixtures thereof. In one embodiment, the fillers of the present disclosure exhibit an aspect ratio of at least 3, 4, 5, 6, 7, 8, 9, 10, 11, 12, 13, 14, or 15 to 1. In one embodiment, the filler aspect ratio is 6:1 or greater. In another embodiment, the filler aspect ratio is 10:1 or greater, and in another embodiment, the aspect ratio is 12:1 or greater. In some embodiments, the filler is selected from a group consisting of oxides (e.g., oxides comprising silicon, titanium, magnesium and/or aluminum), nitrides (e.g., nitrides comprising boron and/or silicon) or carbides (e.g., carbides comprising tungsten and/or silicon). In some embodiments, the filler is less than (as a numerical average) 50, 25, 20, 15, 12, 10, 8, 6, 5, 4, or 2 microns in all dimensions.

In yet another embodiment, carbon fiber and graphite can be used in combination with other fillers to increase mechanical properties. However, oftentimes care must be taken to keep the loading of graphite and/or carbon fiber below 10%, since graphite and carbon fiber fillers can diminish insulation properties and in many embodiments, diminished electrical insulation properties is not desirable. In some embodiments, the filler is coated with a coupling agent. In some embodiments, the filler is coated with an aminosilane coupling agent. In some embodiments, the filler is coated with a dispersant. In some embodiments, the filler is coated with a combination of a coupling agent and a dispersant. Alternatively, the coupling agent and/or dispersant can be incorporated directly into the polyimide film and not necessarily coated onto the filler.

In some embodiments, a filtering system is used to ensure that the final polyimide film will not contain discontinuous domains greater than the desired maximum filler size. In some embodiments, the filler is subjected to intense dispersion energy, such as agitation and/or high shear mixing or media milling or other dispersion techniques, including the use of dispersing agents, when incorporated into the polyimide film (or incorporated into a polyimide film precursor) to inhibit unwanted agglomeration above the desired maximum filler size. As the aspect ratio of the filler increases, so too does the tendency of the filler to align or otherwise position itself between the outer surfaces of the polyimide film, thereby resulting in a increasingly smooth polyimide film, particularly as the filler size decreases.

Generally speaking, polyimide film smoothness is desirable, since surface roughness: i. can interfere with the functionality of the layer or layers deposited on top, ii. can increase the probability of electrical or mechanical defects, and iii. can diminish property uniformity along the polyimide film. In one embodiment, the filler (and any other discontinuous domains) are sufficiently dispersed during polyimide film formation, such that the filler (and any other discontinuous domains) are sufficiently between the surfaces of the polyimide film upon polyimide film formation to provide a final polyimide film having an average surface roughness (Ra) of less than 1000, 750, 500 or 400 nanometers. Surface roughness as provided herein can be determined by optical surface profilometry to provide Ra values, such as, by measuring on a Veeco Wyco NT 1000 Series instrument in VSI mode at 25.4× or 51.2× utilizing Wyco Vision 32 software.

In some embodiments, the filler is chosen so that it does not itself degrade or produce off-gasses at the desired processing temperatures. Likewise in some embodiments, the filler is chosen so that it does not contribute to degradation of the polymer.

Polyimides used in the assemblies of the present disclosure are derived from: i. at least one aromatic diamine, at least 85, 90, 95, 96, 97, 98, 99, 99.5 or 100 mole percent being a rigid rod type monomer; and ii. at least one aromatic dianhydride, at least 85, 90, 95, 96, 97, 98, 99, 99.5 or 100 mole percent being a rigid rod type monomer. Suitable rigid rod type, aromatic diamine monomers include: 1,4-diaminobenzene (PPD), 4,4′-diaminobiphenyl, 2,2′-bis(trifluoromethyl) benzidene (TFMB), 1,4-naphthalenediamine, and/or 1,5-naphthalenediamine. Suitable rigid rod type, aromatic dianhydride monomers include pyromellitic dianhydride (PMDA), and/or 3,3′,4,4′-biphenyl tetracarboxylic dianhydride (BPDA).

In some embodiments, other monomers may also be considered for up to 15 mole percent of the aromatic dianhydride and/or up to 15 mole percent of the aromatic diamine, depending upon desired properties for any particular application of the present invention, for example: 3,4′-diaminodiphenyl ether (3,4′-ODA), 4,4′-diaminodiphenyl ether (4,4′-ODA), 1,3-diaminobenzene (MPD), 4,4′-diaminodiphenyl sulfide, 9,9′-bis(4-aminophenyl)fluorene, 3,3′,4,4′-benzophenone tetracarboxylic dianhydride (BTDA), 4,4′-oxydiphthalic anhydride (ODPA), 3,3′,4,4′-diphenyl sulfone tetracarboxylic dianhydride (DSDA), 2,2-bis(3,4-dicarboxyphenyl) hexafluoropropane dianhydride (6FDA), and mixtures thereof. Polyimides of the present disclosure can be made by methods well known in the art and their preparation need not be discussed in detail here.

In some embodiments, the polyimide film is manufactured by incorporating the filler into a polyimide film precursor material, such as, a solvent, monomer, prepolymer and/or polyamic acid composition. Ultimately, a filled polyamic acid composition is generally cast into a film, which is subjected to drying and curing (chemical and/or thermal curing) to form a filled polyimide free-standing or non free-standing film. Any conventional or non-conventional method of manufacturing filled polyimide films can be used in accordance with the present disclosure. The manufacture of filled polyimide films is well known and need not be further described here. In one embodiment, the polyimide used in an assembly of the present disclosure has a high glass transition temperature (Tg) of greater than 300, 310, 320, 330, 340, 350, 360, 370 380, 390 or 400° C. A high Tg generally helps maintain mechanical properties, such as storage modulus, at high temperatures.

In some embodiments, the crystallinity and amount of crosslinking of the polyimide film can aid in storage modulus retention. In one embodiment, the polyimide film storage modulus (as measured by dynamic mechanical analysis, DMA) at 480° C. is at least: 400, 450, 500, 550, 600, 650, 700, 750, 800, 850, 900, 950, 1000, 1100, 1200, 1300, 1400, 1500, 1600, 1800, 2000, 2200, 2400, 2600, 2800, 3000, 3500, 4000, 4500, or 5000 MPa.

In some embodiments, the polyimide film used in an assembly of the present disclosure has an isothermal weight loss of less than 1, 0.75, 0.5 or 0.3 percent at 500° C. over about 30 minutes in an inert environment, such as, in a vacuum or under nitrogen or other inert gas. Polyimides used in the assemblies of the present disclosure have high dielectric strength, generally higher than common inorganic insulators. In some embodiments, polyimides used in the assemblies of the present disclosure have a breakdown voltage equal to or greater than 10 V/micrometer.

In some embodiments, electrically insulating fillers may be added to modify the electrical properties of the polyimide film. In some embodiments, it is important that the polyimide film be free of pinholes or other defects (foreign particles, gels, filler agglomerates or other contaminates) that could adversely impact the electrical integrity and dielectric strength of the polyimide film, and this can generally be addressed by filtering. Such filtering can be done at any stage of the polyimide film manufacture, such as, filtering solvated filler before or after it is added to one or more monomers and/or filtering the polyamic acid, particularly when the polyamic acid is at low viscosity, or otherwise, filtering at any step in the manufacturing process that allows for filtering. In one embodiment, such filtering is conducted at the minimum suitable filter pore size or at a level just above the largest dimension of the selected filler material.

A single layer polyimide film can be made thicker in an attempt to decrease the effect of defects caused by unwanted (or undesirably large) discontinuous phase material within the polyimide film. Alternatively, multiple layers of polyimide may be used to diminish the harm of any particular defect (unwanted discontinuous phase material of a size capable of harming desired properties) in any particular layer, and generally speaking, such multilayers will have fewer defects in performance compared to a single polyimide layer of the same thickness. Using multiple layers of polyimide films can diminish or eliminate the occurrence of defects that may span the total thickness of the polyimide film, because the likelihood of having defects that overlap in each of the individual layers tends to be extremely small. Therefore, a defect in any one of the layers is much less likely to cause an electrical or other type failure through the entire thickness of the polyimide film. In some embodiments, the polyimide film comprises two or more polyimide layers. In some embodiments, the polyimide layers are the same. In some embodiments, the polyimide layers are different. In some embodiments, the polyimide layers independently may comprise a thermally stable filler, reinforcing fabric, inorganic paper, sheet, scrim or combinations thereof. Optionally, 0-55 weight percent of the polyimide film also includes other ingredients to modify properties as desired or required for any particular application.

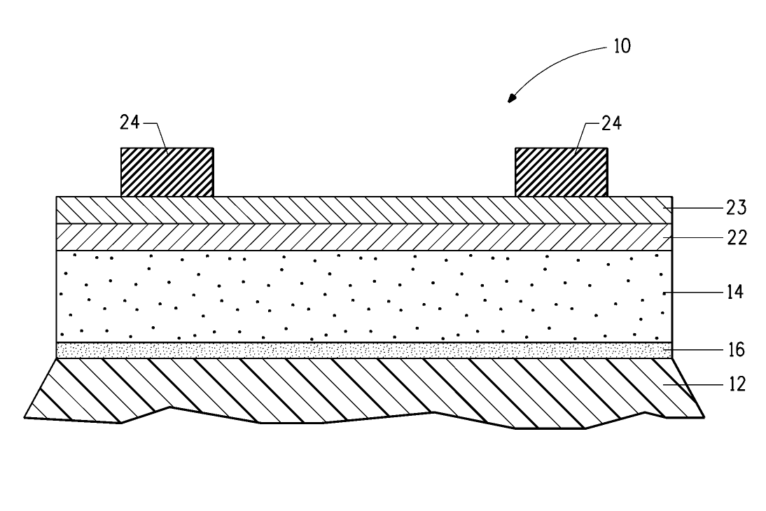

Referring now to FIG. 1, an embodiment of the present disclosure is illustrated as a thin-film solar cell, indicated generally at 10. The thin-film solar cell 10 includes a flexible polyimide film substrate 12 as described and discussed above. A bottom electrode 16 (comprising molybdenum, for example) is applied onto the flexible polyimide film substrate 12, such as, by sputtering, evaporation deposition or the like. A semiconductor absorber layer 14 (comprising Cu(In, Ga)Se₂, for example) is deposited over the bottom electrode 16. The deposition of the semiconductor absorber layer 14 onto the bottom electrode 16 and the flexible polyimide film substrate 12 can be by any of a variety of conventional or non-conventional techniques including, but limited to, casting, laminating and the like. Deposition processes for semiconductor absorber layer 14 are well known and need not be further described here (examples of such deposition processes are discussed and described in U.S. Pat. No. 5,436,204 and U.S. Pat. No. 5,441,897).

An optional adhesion layer or adhesion promoter (not shown) can be used to increase adhesion between any of the above described layers. In one embodiment, the flexible polyimide film substrate 12 is thin and flexible, i.e., approximately 5 microns to approximately 100 microns, in order that the thin-film solar cell 10 is lightweight, or the flexible polyimide film substrate 12 can be thick and rigid to improve handling of the thin-film solar cell 10.

To complete the construction of the thin-film solar cell 10 in this particular embodiment, additional optional layers can be applied. For example, the CIGS absorber layer 14 can be paired (e.g., covered) with a II/VI film 22 to form a photoactive heterojunction. In some embodiments, the II/VI film 22 is constructed from cadmium sulfide (CdS). Constructing the II/VI films 22 from other materials including, but not limited to, cadmium zinc sulfide (CdZnS) and/or zinc selenide (ZnSe) is also within the scope of the present disclosure.

A transparent conducting oxide (TCO) layer 23 for collection of current is applied to the II/VI film. Preferably, the transparent conducting oxide layer 23 is constructed from zinc oxide (ZnO), although constructing the transparent conducting oxide layer 23 from other materials is also within the scope of the present disclosure.

A suitable grid contact 24 or other suitable collector is deposited on the upper surface of the TCO layer 23 when forming a stand-alone thin-film solar cell 10. The grid contact 24 can be formed from various materials but should have high electrical conductivity and form a good ohmic contact with the underlying TCO layer 23. In some embodiments, the grid contact 24 is constructed from a metal material, although constructing the grid contact 24 from other materials including, but not limited to, aluminum, indium, chromium, or molybdenum, with an additional conductive metal overlayment, such as copper, silver, or nickel is within the scope of the present disclosure.

Also, one or more anti-reflective coatings (not shown) can be applied to the grid contact 24 to improve the collection of incident light by the thin-film solar cell 10. As understood by a person skilled in the art, any suitable anti-reflective coating is within the scope of the present disclosure.

### EXAMPLES

The invention will be further described in the following examples, which are not intended to limit the scope of the invention described in the claims. In these examples, “prepolymer” refers to a lower molecular weight polymer made with a slight stoichiometric excess of diamine monomer (about 2%) to yield a Brookfield solution viscosity in the range of about 50-100 poise at 25° C. Increasing the molecular weight (and solution viscosity) was accomplished by adding small incremental amounts of additional dianhydride in order to approach stoichiometric equivalent of dianhydride to diamine.

### Example 1

BPDA/PPD prepolymer (69.3 g of a 17.5 wt % solution in anhydrous DMAC) was combined with 5.62 g of acicular TiO₂ (FTL-110, Ishihara Corporation, USA) and the resulting slurry was stirred for 24 hours. In a separate container, a 6 wt % solution of pyromellitic anhydride (PMDA) was prepared by combining 0.9 g of PMDA (Aldrich 412287, Allentown, Pa.) and 15 ml of DMAC.

The PMDA solution was slowly added to the prepolymer slurry to achieve a final viscosity of 653 poise. The formulation was stored overnight at 0° C. to allow it to degas.

The formulation was cast using a 25 mil doctor blade onto a surface of a glass plate to form a 3″×4″ film. The glass was pretreated with a release agent to facilitate removal of the polyimide film from the glass surface. The film was allowed to dry on a hot plate at 80° C. for 20 minutes. The film was subsequently lifted off the surface, and mounted on a 3″×4″ pin frame.

After further drying at room temperature under vacuum for 12 hours, the mounted film was placed in a furnace (Thermolyne, F6000 box furnace). The furnace was purged with nitrogen and heated according to the following temperature protocol:

| | |
|---|---|
| 125° C. | (30 min) |
| 125° C. to 350° C. | (ramp at 4° C./min) |
| 350° C. | (30 min) |
| 350° C. to 450° C. | (ramp at 5° C./min) |
| 450° C. | (20 min) |
| 450° C. to 40° C. | (cooling at 8° C./min) |

### Comparative Example A

An identical procedure as described in Example 1 was used, except that no TiO₂ filler was added to the prepolymer solution. The final viscosity, before casting, was 993 poise.

### Example 2

The same procedure as described in Example 1 was used, except that 69.4 g of BPDA/PPD prepolymer (17.5 wt % in DMAC) was combined with 5.85 g of TiO₂ (FTL-200, Ishihara USA). The final viscosity of the formulation prior to casting was 524 poise.

### Example 3

The same procedure as described in Example 1 was used, except that 69.4 g of BPDA/PPD prepolymer was combined with 5.85 g of acicular TiO₂ (FTL-300, Ishihara USA). The final viscosity prior to casting was 394 poise.

### Example 4A

The same procedure as described in Example 1 was used, except that 69.3 g of BPDA/PPD prepolymer (17.5 wt % in DMAC) was combined with 5.62 g of acicular TiO₂ (FTL-100, Ishihara USA).

The material was filtered through 80 micron filter media (Millipore, polypropylene screen, 80 micron, PP 8004700) before the addition of the PMDA solution in DMAC.

The final viscosity before casting was 599 poise.

### Example 4

The same procedure as described in Example 1 was followed, except that 139 g of BPDA/PPD prepolymer (17.5 wt % in DMAC) was combined with 11.3 g of acicular TiO₂ (FTL-100). The mixture of BPDA/PPD prepolymer with acicular TiO₂ (FTL-110) was placed in a small container. A Silverson Model L4RT high-shear mixer (Silverson Machines, LTD, Chesham Baucks, England) equipped with a square-hole, high-shear screen was used to mix the formulation (with a blade speed of approximately 4000 rpm) for 20 minutes. An ice bath was used to keep the formulation cool during the mixing operation.

The final viscosity of the material before casting was 310 poise.

### Example 5

The same procedure as described in Example 4 was used, except that 133.03 g of BPDA/PPD prepolymer (17.5 wt % in DMAC) was combined with 6.96 g of acicular TiO₂ (FTL-110).

The material was placed a small container and mixed with a high-shear mixer (with a blade speed of approximately 4000 rpm) for approximately 10 min. The material was then filtered through 45 micron filter media (Millipore, 45 micron polypropylene screen, PP4504700).

The final viscosity was approximately 1000 poise, prior to casting.

### Example 6

The same procedure as described in Example 5 was used, except that 159.28 g of BPDA/PPD prepolymer was combined with 10.72 g of acicular TiO₂ (FTL-110). The material was mixed with a high-shear mixer for 5-10 minutes.

The final formulation viscosity prior to casting was approximately 1000 poise.

### Example 7

The same procedure as described in Example 5 was used, except that 157.3 g of BPDA/PPD prepolymer was combined with 12.72 grams of acicular TiO₂ (FTL-110). The material was blended with the high shear mixer for approximately 10 min.

The final viscosity prior to casting was approximately 1000 poise.

### Example 8

A procedure similar to that described in Example 5 was used, except that 140.5 g of DMAC was combined with 24.92 g of TiO₂ (FTL-110). This slurry was blended using a high-shear mixer for approximately 10 minutes.

This slurry (57.8 g) was combined with 107.8 g of BPDA/PPD prepolymer (17.5 wt % in DMAC) in a 250 ml, 3-neck, round-bottom flask. The mixture was slowly agitated with a paddle stirrer overnight under a slow nitrogen purge. The material was blended with the high-shear mixer a second time (approximately 10 min, 4000 rpm) and then filtered through 45 micron filter media (Millipore, 45 micron polypropylene, PP4504700). The final viscosity was 400 poise.

### Example 9

The same procedure as described in Example 8 was used, except that 140.49 g of DMAC was combined with 24.89 g of talc (Flex Talc 610, Kish Company, Mentor, Ohio). The material was blended using the high-shear mixing procedure described in Example 8.

This slurry (69.34 g) was combined with 129.25 g of BPDA/PPD prepolymer (17.5 wt % in DMAC), mixed using a high-shear mixer a second time, and then filtered through 25 micron filter media (Millipore, polypropylene, PP2504700) and cast at 1600 poise.

### Example 10

This formulation was prepared at a similar volume % (with TiO₂, FTL-110) to compare with Example 9. The same procedure as described in Example 1 was used. 67.01 g of BPDA/PPD prepolymer (17.5 wt %) was combined with 79.05 grams of acicular TiO₂ (FTL-110) powder. The formulation was finished to a viscosity of 255 poise before casting.

A Dynamic Mechanical Analysis (DMA) instrument was used to characterize the mechanical behavior of Comparative Example A and Example 10. DMA operation was based on the viscoelastic response of polymers subjected to a small oscillatory strain (e.g., 10 μm) as a function of temperature and time (TA Instruments, New Castle, DE, USA, DMA 2980). The polyimide films were operated in tension and multifrequency-strain mode, where a finite size of rectangular specimen was clamped between stationary jaws and movable jaws. Samples of 6-6.4 mm width, 0.03-0.05 mm thickness and 10 mm length in the MD direction were fastened with 3 in-lb torque force. The static force in the length direction was 0.05 N with autotension of 125%. The polyimide film was heated at frequency of 1 Hz from 0° C. to 500° C. at 3° C./min rate. The storage modulii at room temperature, 500 and 480° C. are recorded on Table 1.

The coefficient of thermal expansion of Comparative Example A and Example 10 were measured by thermomechanical analysis (TMA). A TA Instrument model 2940 was set up in tension mode and furnished with an N₂ purge of 30-50 ml/min rate and a mechanical cooler. The film was cut to a 2.0 mm width in the MD (casting) direction and clamped lengthwise between the film clamps allowing a 7.5-9.0 mm length. The preload tension was set for 5 grams force. The film was then subjected to heating from 0° C. to 400° C. at 10° C./min rate with 3 minutes hold, cooling back down to 0° C. and reheating to 400° C. at the same speed. The calculations of thermal expansion coefficient in units of μm/m-° C. (or ppm/° C.) from 60° C. to 400° C. were reported for the casting direction (MD) for the second heating cycle over 60° C. to 400° C., and also over 60° C. to 350° C.

A thermogravimetric analysis instrument (TA, Q5000) was used for sample measurements of weight loss. Measurements were performed in flowing nitrogen. The temperature program involved heating at a rate of 20° C./min to 500° C. The weight loss after holding for 30 minutes at 500° C. is calculated by normalizing to the weight at 200° C., where any adsorbed water was removed, to determine the decomposition of polymer at temperatures above 200° C.

TABLE 1

| | Storage Modulus | CTE, | TGA, % wt loss |
|---|---|---|---|
| | (DMA) at 500° C. | ppm/° C. | at 500° C., 30 min, |
| | (480° C.), | 400 C, | normalized to |
| Example # | MPa | (350° C.) | weight at 200° C. |
| 10 | 4000 (4162) | 17.9, (17.6) | 0.20 |
| Comparative A | Less than 200 (less | 11.8, (10.8) | 0.16 |
| | than 200) | | |

### Comparative Example B

The same procedure as described in Example 8 was used, with the following differences. 145.06 g of BPDA/PPD prepolymer was used (17.5 wt % in DMAC).

127.45 grams of Wallastonite powder (Vansil HR325, R. T. Vanderbilt Company, Norwalk Conn.) having a smallest dimension greater than 800 nanometers (as calculated using an equivalent cylindrical width defined by a 12:1 aspect ratio and an average equivalent spherical size distribution of 2.3 microns) was combined with 127.45 grams of DMAC and high shear mixed according to the procedure of Example 8.

145.06 g of BPDA/PPD prepolymer (17.5 wt % in DMAC) was combined with 38.9 grams of the high shear mixed slurry of wollastonite in DMAC. The formulation was high shear mixed a second time, according to the procedure of Example 8.

The formulation was finished to a viscosity of 3100 poise and then diluted with DMAC to a viscosity of 600 poise before casting.

### Measurement of High Temperature Creep

A DMA (TA Instruments Q800 model) was used for a creep/recovery study of polyimide film specimens in tension and customized controlled force mode. A pressed polyimide film of 6-6.4 mm width, 0.03-0.05 mm thickness and 10 mm length was clamped between stationary jaws and movable jaws in 3 in-lb torque force. The static force in the length direction was 0.005N. The polyimide film was heated to 460° C. at 20° C./min rate and held at 460° C. for 150 min. The creep program was set at 2 MPa for 20 min, followed by recovery for 30 min with no additional force other than the initial static force of (0.005N). The creep/recovery program was repeated for 4 MPa and 8 MPa and the same time intervals as that for 2 MPa.

In Table 2 below are tabulated the strain and the recovery following the cycle at 8 MPa (more precisely, the maximum stress being from about 7.4 to 8.0 MPa). The elongation is converted to a unitless equivalent strain by dividing the elongation by the starting polyimide film length. The strain at 8 MPa (more precisely, the maximum stress being from about 7.4 to 8.0 MPa) and 460° C. is tabulated, “emax”. The term “e max” is the dimensionless strain which is corrected for any changes in the polyimide film due to decomposition and solvent loss (as extrapolated from the stress free slope) at the end of the 8 MPa cycle (more precisely, the maximum stress being from about 7.4 to 8.0 MPa). The term “e rec” is the strain recovery immediately following the 8 MPa cycle (more precisely, the maximum stress being from about 7.4 to 8.0 MPa), but at no additional applied force (other than the initial static force of 0.005 N), which is a measure of the recovery of the material, corrected for any changes in polyimide film due to decomposition and solvent loss as measured by the stress free slope). The parameter, labeled “stress free slope,” is also tabulated in units of dimensionless strain/min and is the change in strain when the initial static force of 0.005 N is applied to the sample after the initial application of the 8 Mpa stress (more precisely, the maximum stress being from about 7.4 to 8.0 MPa). This slope is calculated based on the dimensional change in the polyimide film (“stress free strain”) over the course of 30 min following the application of the 8 MPa stress cycle (more precisely, the maximum stress being from about 7.4 to 8.0 MPa). Typically the stress free slope is negative. However, the stress free slope value is provided as an absolute value and hence is always a positive number.

The third column, e plast, describes the plastic flow, and is a direct measure of high temperature creep, and is the difference between e max and e rec.

In general, a material which exhibits the lowest possible strain (e max), the lowest amount of stress plastic flow (e plast) and a low value of the stress free slope is desirable.

TABLE 2

| | | | | | Plastic | | | |
|---|---|---|---|---|---|---|---|---|
| | | Applied | e max (strain | | deformation | Absolute Value | Wt fraction of | Vol fraction |
| | | Stress | at applied | | ((eplast) = e | Stress Free | inorganic filler | inorganic filler |
| Example | Additive | (MPA)* | stress) | e rec | max − e rec )) | Slope (/min) | in polyimide | in polyimide* |
| Example 1 | TiO₂ (FLT-110) | 7.44 | 4.26E−03 | 3.87E−03 | 3.89E−04 | 2.82E−06 | 0.338 | 0.147 |
| Comparative | None | 7.52 | 1.50E−02 | 1.40E−02 | 9.52E−04 | 9.98E−06 | | |
| Example A | | | | | | | | |
| Example 2* | TiO₂ (FLT-200) | 4.64 | 3.45E−03 | 3.09E−03 | 3.67E−04 | 2.88E−06 | 0.346 | 0.152 |
| Example 3 | TiO₂ (FLT-300) | 7.48 | 2.49E−03 | 2.23E−03 | 2.65E−04 | 1.82E−06 | 0.346 | 0.152 |
| | | | | | | (82% lower | | |
| | | | | | | than compara- | | |
| | | | | | | tive example) | | |
| Example 4 A | TiO₂ (FLT-100) | 7.48 | 3.56E−03 | 3.18E−03 | 3.77E−04 | 3.40E−06 | 0.338 | 0.147 |
| Example 4 | TiO₂ (FLT-110) | 7.45 | 2.42E−03 | 2.20E−03 | 2.16E−04 | 1.73E−06 | 0.338 | 0.147 |
| Example 5 | TiO₂ (FLT-110) | 7.48 | 7.83E−03 | 7.05E−-03 | 7.84E−04 | 5.61E−06 | 0.247 | 0.100 |
| Example 6 | TiO₂ (FLT-110) | 7.46 | 4.35E−03 | 3.97E−03 | 3.82E−04 | 2.75E−06 | 0.297 | 0.125 |
| Example 7 | TiO₂ (FLT-110) | 7.46 | 3.32E−03 | 3.02E−03 | 3.00E−04 | 1.98E−06 | 0.337 | 0.147 |
| Example 8 | TiO₂ (FLT-110) | 8.03 | 3.83E−03 | 3.53E−03 | 2.97E−04 | 3.32E−06 | 0.337 | 0.146 |
| Example 9 | Talc | 8.02 | 5.65E−03 | 4.92E−03 | 7.23E−04 | 7.13E−06 | 0.337 | 0.208 |
| Example 10 | TiO₂ (FTL-110) | 7.41 | 1.97E−03 | 1.42E−04 | 2.66E−04 | 1.37E−06 | 0.426 | 0.200 |
| Comparative | Wollastonite | 8.02 | 1.07E−02 | 9.52E−03 | 1.22E−03 | 1.15E−05 | 0.255 | 0.146 |
| B | powder | | | | | | | |

*Maximum applied stress was in a range from 7.4 to 8.0 MPa, except for Example 2 which was conducted at 4.64 MPa

Table 2 provides filler loadings in both weight fraction and volume fraction. Filler loadings of similar volume fractions are generally a more accurate comparison of fillers, since filler performance tends to be primarily a function of space occupied by the filler, at least with respect to the present disclosure. The volume fraction of the filler in the polyimide films was calculated from the corresponding weight fractions, assuming a fully dense polyimide film and using these densities for the various components: 1.42 g/cc for density of polyimide; 4.2 g/cc for density of acicular TiO2; 2.75 g /cc for density of talc; and 2.84 g/cc for wollastonite.

### Example 11

168.09 grams of a polyamic acid (PAA) prepolymer solution prepared from BPDA and PPD in DMAC (dimethylacetamide) with a slight excess of PPD (15 wt % PAA in DMAC)) were blended with 10.05 grams of Flextalc 610 talc for 2 minutes in a Thinky ARE-250 centrifugal mixer to yield an off-white dispersion of the filler in the PAA solution.

The dispersion was then pressure-filtered through a 45 micron polypropylene filter membrane. Subsequently, small amounts of PMDA (6 wt % in DMAC) were added to the dispersion with subsequent mixing to increase the molecular weight and thereby the solution viscosity to about 3460 poise. The filtered solution was degassed under vacuum to remove air bubbles and then this solution was coated onto a piece of Duofoil® aluminum release sheet (˜9 mil thick), placed on a hot plate, and dried at about 80-100° C. for 30 min to 1 hour to a tack-free film.

The film was subsequently carefully removed from the substrate and placed on a pin frame and then placed into a nitrogen purged oven, ramped from 40° C. to 320° C. over about 70 minutes, held at 320° C. for 30 minutes, then ramped to 450° C. over 16 minutes and held at 450° C. for 4 minutes, followed by cooling. The film on the pin frame was removed from the oven and separated from the pin frame to yield a filled polyimide film (about 30 wt % filler).

The approximately 1.9 mil (approximately 48 micron) polyimide film exhibited the following properties.

Storage Modulus (E′) by Dynamic Mechanical Analysis (TA Instruments, DMA-2980, 5° C./min) of 12.8 GPa at 50° C. and 1.3 GPa at 480° C., and a Tg (max of tan delta peak) of 341° C.

Coefficient of thermal expansion (TA Instruments, TMA-2940, 10° C./min, up to 380° C., then cool and rescan to 380° C.) of 13 ppm/° C. and 16 ppm/° C. in the cast and transverse directions, respectively, when evaluated between 50-350° C. on the second scan.

Isothermal weight loss (TA Instruments, TGA 2050, 20° C./min up to 500° C. then held for 30 min at 500° C.) of 0.42% from beginning to end of isothermal hold at 500° C., where the analysis is done in an inert environment, such as, under vacuum or under nitrogen or other inert gas.

### Comparative Example C

200 grams of a polyamic acid (PAA) prepolymer solution prepared from BPDA and PPD in DMAC with a slight excess of PPD (15 wt % PAA in DMAC,) were weighed out. Subsequently, small amounts of PMDA (6 wt % in DMAC) were added stepwise in a Thinky ARE-250 centrifugal mixer to increase the molecular weight and thereby the solution viscosity to about 1650 poise. The solution was then degassed under vacuum to remove air bubbles and then this solution was coated onto a piece of Duofoil® aluminum release sheet (˜9 mil thick), placed on a hot plate and dried at about 80-100° C. for 30 min to 1 hour to a tack-free film. The film was subsequently carefully removed from the substrate and placed on a pin frame then placed into a nitrogen purged oven, ramped from 40° C. to 320° C. over about 70 minutes, held at 320° C. for 30 minutes, then ramped to 450° C. over 16 minutes and held at 450° C. for 4 minutes, followed by cooling. The film on the pin frame was removed from the oven and separated from the pin frame to yield a filled polyimide film (0 wt % filler).

The approximately 2.4 mil (approximately 60 micron) polyimide film exhibited the following properties.

Storage modulus (E′) by Dynamic Mechanical Analysis (TA Instruments, DMA-2980, 5° C./min) of 8.9 GPa at 50° C., and 0.3 GPa at 480° C., and a Tg (max of tan delta peak) of 348° C.

Coefficient of thermal expansion (TA Instruments, TMA-2940, 10° C./min, up to 380° C., then cool and rescan to 380° C.) of 18 ppm/° C. and 16 ppm/° C. in the cast and transverse directions, respectively, when evaluated between 50-350° C. on the second scan.

Isothermal weight loss (TA Instruments, TGA 2050, 20° C./min up to 500° C. then held for 30 min at 500° C.) of 0.44% from beginning to end of isothermal hold at 500° C., where the analysis is done in an inert environment, such as, under vacuum or under nitrogen or other inert gas.

### Example 12

In a similar manner to Example 11, a polyamic acid polymer with Flextalc 610 at about 30 wt % was cast onto a 5 mil polyester film. The cast film on the polyester was placed in a bath containing approximately equal amounts of acetic anhydride and 3-picoline at room temperature. As the cast film imidized in the bath, it began to release from the polyester. At this point, the cast film was removed from the bath and the polyester, placed on a pinframe, and then placed in a oven and ramped as described in Example 11. The resulting talc-filled polymide film exhibited a CTE by TMA (as in Example 11) of 9 ppm/° C. and 6 ppm/° C. in the cast and transverse directions, respectively.

Note that not all of the activities described above in the general description or the examples are required, that a portion of a specific activity may not be required, and that further activities may be performed in addition to those described. Still further, the order in which each of the activities are listed are not necessarily the order in which they are performed. After reading this specification, skilled artisans will be capable of determining what activities can be used for their specific needs or desires.

In the foregoing specification, the invention has been described with reference to specific embodiments. However, one of ordinary skill in the art appreciates that various modifications and changes can be made without departing from the scope of the invention as set forth in the claims below. Accordingly, the specification and any figures are to be regarded in an illustrative rather than a restrictive sense and all such modifications are intended to be included within the scope of the invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims.

When an amount, concentration, or other value or parameter is given as either a range, preferred range or a list of upper values and lower values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

What is claimed is:

1. An assembly comprising:
A) a polyimide film comprising:
a) an aromatic polyimide in an amount from 40 to 95 weight percent of the polyimide film, the polyimide being derived from:
i) at least one aromatic dianhydride, at least 85 mole percent of said aromatic dianhydride being a rigid rod type dianhydride, and
ii) at least one aromatic diamine, at least 85 mole percent of said aromatic diamine being a rigid rod type diamine; and
b) a filler that:
i) is less than 800 nanometers in at least one dimension;
ii) has an aspect ratio greater than 3:1;
iii) is less than the thickness of the polyimide film in all dimensions; and
iv) is present in an amount from 5 to 60 weight percent of the total weight of the polyimide film,
the polyimide film having a thickness from 8 to 150 microns,
B) an absorber layer, and
C) an electrode supported by said polyimide film,
said electrode being between the absorber layer and the polyimide film and said electrode being in electrical communication with the absorber layer.

2. An assembly in accordance with claim 1, wherein the filler is a platelet, needle-like or fibrous, and the absorber layer is a CIGS/CIS absorber layer.

3. An assembly in accordance with claim 1, wherein the filler is needle-like or fibrous, and the assembly further comprises a plurality of monolithically integrated CIGS/CIS photovoltaic cells.

4. An assembly in accordance with claim 1, wherein the filler is smaller than 600 nm in at least one dimension, and the assembly further comprises a plurality of monolithically integrated CIGS/CIS photovoltaic cells

5. An assembly in accordance with claim 1, wherein the filler is smaller than 400 nm in at least one dimension, and the assembly further comprises a plurality of monolithically integrated CIGS/CIS photovoltaic cells.

6. An assembly in accordance with claim 1, wherein the filler is smaller than 200 nm in at least one dimension, and the assembly further comprises a plurality of monolithically integrated CIGS/CIS photovoltaic cells.

7. An assembly in accordance with claim 1, wherein the filler is selected from a group consisting of oxides, nitrides, carbides and combinations thereof, and the assembly further comprises a plurality of monolithically integrated CIGS/CIS photovoltaic cells.

8. An assembly in accordance with claim 1, wherein the filler comprises oxygen and at least one member of the group consisting of aluminum, silicon, titanium, magnesium and combinations thereof.

9. An assembly in accordance with claim 1, wherein the filler comprises platelet talc.

10. An assembly in accordance with claim 1, wherein the filler comprises acicular titanium dioxide.

11. An assembly in accordance with claim 1, wherein the filler comprises an acicular titanium dioxide, at least a portion of which is coated with an aluminum oxide.

12. An assembly in accordance with claim 1, wherein:
a) the rigid rod type dianhydride is selected from a group consisting of 3,3′,4,4′-biphenyl tetracarboxylic dianhydride (BPDA), pyromellitic dianhydride (PMDA), and mixtures thereof; and
b) the rigid rod type diamine is selected from 1,4-diaminobenzene (PPD), 4,4′-diaminobiphenyl, 2,2′-bis(trifluoromethyl) benzidene (TFMB), 1,5-naphthalenediamine, 1,4-naphthalenediamine, and mixtures thereof.

13. An assembly in accordance with claim 1, wherein at least 50 mole percent of the diamine is 1,5-naphthalenediamine.

14. An assembly in accordance with claim 1, wherein the polyimide film comprises a coupling agent, a dispersant or a combination thereof.

15. An assembly in accordance with claim 1, wherein the filler is selected from a group consisting of oxides, nitrides, carbides and mixtures thereof, and the polyimide film has at least one of the following properties: (i) a Tg greater than 300° C., (ii) a dielectric strength greater 500 volts per 25.4 microns, (iii) an isothermal weight loss under inert conditions of less than 1% at 500° C. over 30 minutes, (iv) an in-plane CTE of less than 25 ppm/° C., (v) an absolute value stress free slope of less than 10 times (10)⁻⁶ per minute, and (vi) an eₘₐₓ of less than 1% at 7.4-8 MPa.

16. An assembly in accordance with claim 1, wherein the filler is selected from a group consisting of oxides, nitrides, carbides and mixtures thereof, and the polyimide film has at least two of the following properties: (i) a Tg greater than 300° C., (ii) a dielectric strength greater than 500 volts per 25.4 microns, (iii) an isothermal weight loss under inert conditions of less than 1% at 500° C. over 30 minutes, (iv) an in-plane CTE of less than 25 ppm/° C., (v) an absolute value stress free slope of less than 10 times (10)⁻⁶ per minute, and (vi) an e_{max of less than} 1% at 7.4-8 MPa.

17. An assembly in accordance with claim 1, wherein the filler is selected from a group consisting of oxides, nitrides, carbides and mixtures thereof, and the polyimide film has at least three of the following properties: (i) a Tg greater than 300° C., (ii) a dielectric strength greater than 500 volts per 25.4 microns, (iii) an isothermal weight loss under inert conditions of less than 1% at 500° C. over 30 minutes, (iv) an in-plane CTE of less than 25 ppm/° C., (v) an absolute value stress free slope of less than 10 times (10)⁻⁶ per minute, and (vi) an eₘₐₓ of less than 1% at 7.4-8 MPa.

18. An assembly in accordance with claim 1, wherein the filler is selected from a group consisting of oxides, nitrides, carbides and mixtures thereof, and the polyimide film has at least four of the following properties: (i) a Tg greater than 300° C., (ii) a dielectric strength greater than 500 volts per 25.4 microns, (iii) an isothermal weight loss under inert conditions of less than 1% at 500° C. over 30 minutes, (iv) an in-plane CTE of less than 25 ppm/° C., (v) an absolute value stress free slope of less than 10 times (10)⁻⁶ per minute, and (vi) an eₘₐₓ of less than 1% at 7.4-8 MPa.

19. An assembly in accordance with claim 1, wherein the filler is selected from a group consisting of oxides, nitrides, carbides and mixtures thereof, and the polyimide film has at least five of the following properties: (i) a Tg greater than 300° C., (ii) a dielectric strength greater than 500 volts per 25.4 microns, (iii) an isothermal weight loss under inert conditions of less than 1% at 500° C. over 30 minutes, (iv) an in-plane CTE of less than 25 ppm/° C., (v) an absolute value stress free slope of less than 10 times (10)⁻⁶ per minute, and (vi) an eₘₐₓ of less than 1% at 7.4-8 MPa.

20. An assembly in accordance with claim 1, wherein the filler is selected from a group consisting of oxides, nitrides, carbides and mixtures thereof, and the polyimide film has the following properties: (i) a Tg greater than 300° C., (ii) a dielectric strength greater than 500 volts per 25.4 microns, (iii) an isothermal weight loss under inert conditions of less than 1% at 500 ° C. over 30 minutes, (iv) an in-plane CTE of less than 25 ppm/° C., (v) an absolute value stress free slope of less than 10 times (10)⁻⁶ per minute, and (vi) an eₘₐₓ of less than 1% at 7.4-8 MPa.

21. An assembly in accordance with claim 1, wherein the polyimide film comprises two or more layers.

22. An assembly in accordance with claim 1, wherein the polyimide film is reinforced with a thermally stable, inorganic: fabric, paper, sheet, scrim or a combination thereof.
